(19) United States
(12) Patent Application Publication
(10) Pub. No.: US 2006/0269016 A1
(43) Pub. Date: Nov. 30, 2006

(54) Adaptive interpolator for channel estimation

(75) Inventors: Guozhu Long, Fremont, CA (US); Yu-Wen Evan Chang, Fremont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: MediaPhy Corporation, San Jose, CA (US)

(21) Appl. No.: 11/444,124

(22) Filed: May 30, 2006

Related U.S. Application Data
(60) Provisional application No. 60/685,704, filed on May 27, 2005.

(51) Int. Cl. H04L 27/06; H03D 1/04

(52) U.S. Cl. 375/340; 375/346

(57) ABSTRACT

A method for channel estimation in a wireless communication system includes the following steps. Channel transfer function is computed at continual and scattered pilot cells using transmitted and received signals at the continual and scattered pilot cells. Time-domain adaptive interpolation is performed to obtain channel transfer function at non-pilot cells of the scattered pilot tones using the channel transfer function computed at continual and scattered pilot cells. Frequency-domain adaptive interpolation is performed to obtain channel transfer function at non-pilot cells of non-pilot tones using the channel transfer function computed at continual and scattered pilot cells.

### CROSS-REFERENCES TO RELATED APPLICATIONS

This application claims the benefit of U.S. Provisional Application No. 60/685,704, filed May 27, 2005, which is incorporated by reference in its entirety for all purposes.

### BACKGROUND OF THE INVENTION

The present invention relates to wireless communication systems, and more particularly to an improved channel estimation technique for OFDM communication systems.

In communications systems, the information-bearing signals are transmitted from the source to the destination through a communication channel which causes signal distortion. In the receiver, the signal distortions caused by the communication channel have to be properly compensated so that the transmitted signal from the source can be accurately recovered. A typical example of compensating the channel distortion is the equalizer. The equalizer is typically trained, based on some training signals, to some optimal setting. This kind of adaptive equalizer works well for stationary or slow-varying channels. For fast time-varying channels, such as those for wireless communications, the channel variation is often very fast. As a result, the equalizer has to be trained very frequently for the equalizer to track the fast-varying channel characteristics.

OFDM (Orthogonal Frequency Division Multiplexing) is gaining popularity in broadband communications. In OFDM systems, the data signal is distributed to many equally-spaced, mutually-orthogonal sub-carriers. OFDM modulation is typically implemented through the IFFT (Inverse Fast Fourier Transform) in the transmitter, and the FFT (Fast Fourier Transform) in the receiver. FIG. 1 is a block diagram of an OFDM-based wireless receiver.

In FIG. 1, the radio-frequency signal is received by RF tuner 100 via an antenna. The desired signal is selected by the tuner 100, and down-converted and filtered through the down-converter/filter block 110. The output of block 110 is the analog baseband (or passband at much lower frequency than the original radio frequency) signal, which is converted into digital signal by A-to-D block 120. The digital signal is grouped into symbols with symbol boundary properly identified in symbol synchronization block 130, and the guard periods (typically cyclic prefix) removed in block 140 before being provided to FFT block 150. After FFT 150, the signal is in frequency-domain, and the equalizer FEQ 170 is used in the frequency domain. With orthogonality, the sub-carriers do not interfere with each other, so the frequency-domain equalizer (FEQ) can be implemented separately for each sub-carrier (sometimes also called bin or carrier). Since the symbols are separated by some guard time period (cyclic prefix), the inter-symbol-interference (ISI) is avoided. Hence, such an FEQ simply becomes a one-tap complex scaling. This complex tap coefficient can be determined adaptively through training, and may be updated during data transmission. For fast-varying channels, such as wireless communication channels, those coefficients have to be trained frequently.

One way to train those FEQ coefficients is through channel estimation carried out by block 160. Suppose at sub-carrier k and time nT, where T is the symbol interval, the signal transmitted from the transmitter is X(n,k), the channel transfer function is H(n,k), and the received signal at the receiver is Y(n,k). We have Y(n,k)=X(n,k)H(n,k). If H(n,k) is known, we can set the FEQ coefficient to 1/H(n,k), then Y(n,k)/H(n,k)=X(n,k). The channel transfer function is not known to the receiver. So the task here is to estimate H(n,k).

If X(n,k) and Y(n,k) are known, H(n,k)=Y(n,k)/X(n,k) can be estimated. Y(n,k) is available at the receiver. In order for the receiver to know X(n,k), typically, some predefined training signals are transmitted from the transmitter at some particular times/frequencies. For stationary or slow-varying channels, those training signals are typically transmitted in the initial training phase before data transmission starts. Afterwards, X(n,k) is typically obtained through receiver decision or some occasionally transmitted reference signals. For fast-varying channels, the reference signals have to be transmitted from the transmitter frequently at pre-defined times and frequencies so that the receiver can estimate the channel transfer function frequently enough to track the channel variations. The transmission of the reference signal will consume some channel bandwidth, resulting in the reduction of the data transmission rate. Therefore, the reference signal can not be transmitted too frequently. Typically, the reference signals are transmitted only at a small percentage of time/frequency. The receiver takes advantage of those snap-shot training signals to compute the channel transfer function at those particular time/frequency snap-shots, and then estimate the channel transfer functions at all other time/frequencies. After obtaining the channel transfer function estimates H(n,k) for all the time/frequencies, 1/H(n,k) is used as the FEQ coefficient for k-th sub-carrier at time nT. Finally, the estimate of the transmitted signal is obtained as Y(n,k)/H(n,k).

A typical example can be seen in DVB-T specification. DVB-T uses OFDM modulation with 2 k or 8 k sub-carriers. For the 2 k-mode, 45 sub-carriers are used as continual pilot tones. For the 8 k-mode, 177 sub-carriers are used as continual pilot tones. DVB-H specification is based on DVB-T, but tailored to the mobile/handheld applications. In DVB-H, an additional 4 k-mode is defined. FIG. 2 shows the pilot insertion pattern in DVB-T and DVB-H. FIG. 2 will be used to define terminology used throughout this disclosure. In FIG. 2, the horizontal dimension represents frequency domain and the vertical dimension represents time domain. Each black circle will be referred to as a “pilot cell” and each white circle will be referred to as a “data cell” or a “non-pilot cell.” Each row in FIG. 2 corresponds to a distinct “symbol,” and each column will be referred to as a “tone.” A column with only pilot cells (such as the far left and far right columns) will be referred to as a “continual pilot tone,” an a row with only pilot cells will be referred to as a “continual pilot symbol.” Each pilot cell in a continual pilot tone or in a continual pilot symbol will be referred to as a “continual pilot cell.” Each column with both pilot cells and data cells will be referred to as a “scattered pilot tone,” and each row with both pilot cells and data cells will be referred to as a “scattered pilot symbol.” Each pilot cell in a scattered pilot tone or in a scattered pilot symbol will be referred to as a “scattered pilot cell.” A column with only data cells will be referred to as a “non-pilot tone,” and a row with only data cells will be referred to as a “non-pilot symbol.” Note that in FIG. 2, there is no “continual pilot symbol”, nor “non-pilot symbol”.

In FIG. 2, in every symbol, some sub-carriers are used as scattered pilot cells. The scattered pilot cells are 12 carriers apart in frequency and the carrier positions are shifted by three every symbol. As a result, the scattered pilot cells are 4 symbols apart in time. At the rest of times/frequencies except the continual pilot tones, the data signals are transmitted. Since the pilot signals are known to the receiver, they can be used by the receiver to calculate the channel transfer functions at those particular times/frequencies. They are then used to calculate (interpolate) the estimated channel transfer function H(n,k) at all other times/frequencies which are used by the receiver to compensate the channel distortion and detect the data properly. The interpolation is two-dimensional in time and frequency. The challenge here is how to estimate H(n,k) accurately and efficiently.

Typically, the 2-dimensional interpolation may be implemented with two separate one-dimensional interpolations. The interpolation is first done in time-domain at all the scattered pilot tones. Since at a particular scattered pilot tone ki, the pilot cell is sent 4 symbols apart in time X(n+4m,ki), m=0±,1±+,2 . . . . From X(n+4m,ki) and Y(n+4m,ki), we obtain H(n+4m,ki), then H(n+4m+1,ki), H(n+4m+2,ki) and H(n+4m+3,ki) need to be estimated. This is time-domain interpolation. In frequency-domain, the scattered pilot tones are 3 tones apart. The frequency-domain interpolation at time n uses H(n,k+3j), j=0+,1+,2 . . . to estimate H(n,k+3j+b 1), H(n,k+3j+2) at all non-pilot carriers.

Either of the interpolation operations can be implemented with a finite impulse response (FIR) filter. Such a FIR filter may be simply an interpolation filter that is a low-pass filter. If a fixed interpolation filter is used, the bandwidth of the low-pass filter should cover the worst-case channel variation. For DVB-T/DVB-H, the time-domain interpolation filter may be a ¼-passband low-pass filter whose passband should cover the worst-case Doppler frequency; and the frequency-domain interpolation filter may be a ⅓-passband low-pass filter whose passband should cover the worst-case multi-path delay dispersions. The lowpass interpolation filters often use real, symmetric coefficients. For example, for the time-domain interpolation, the filter uses H(4(m-M/2+1),ki), H(4(m-M/2+2),ki), H(4(m-M/2+3),ki), . . . H(4(m−1),ki), H(4m,ki), H(4(m+1),ki), . . . H(4(m+M/2),ki) as input and 3 sets of M real coefficients each to estimate H(4m+1,ki), H(4m+2,ki), and H(4m+3,ki), respectively. Note that H(4(m+1),ki), . . . H(4(m+M/2),ki) are future channel transfer function which are unavailable at time 4m+1, 4m+2 and 4m+3. Obviously, H(4m+1,ki), H(4m+2,ki), and H(4m+3,ki) can not be computed until H(4(m+1),ki), . . . H(4(m+M/2),ki) are available. These filters have basically symmetric coefficients around the center, hence about the same number of H values need to be used in both sides. That means memory space is needed to store about 2 M “future” symbols of the received signals, in addition to some past H values at the pilots. For example, for DVB-T 8 k mode, if M=8, the receiver needs to store 16 “future” symbols each of which has about 8 k complex signals, which requires considerable amount of memory space. Using smaller M can reduce the memory requirement and complexity, but the performance may be degraded. In frequency-domain interpolation, the issue is not the signal storage, but the performance degradation at both boundaries due to the unavailability of H values outside the boundaries. Using real coefficients limits the filter characteristics as well. For many particular channel conditions, using complex coefficients provides much more flexibility, and possibility of performance improvement. The optimal sets of filter coefficients are often pre-computed off-line for the worst-case conditions, stored in ROM and selected according to the mode of operation.

A simpler interpolation method is the linear interpolation. For example, in time-domain interpolation, H(4m+1,ki), H(4m+2,ki), and H(4m+3,ki) are calculated based on H(4m,ki) and H(4m+4,ki). Linear interpolation is much simpler, and there is no boundary problem in the frequency-domain interpolation. However, its performance is typically much worse than the lowpass interpolation filters.

Since the interpolation in time domain requires memory to store future signals, it is sometimes desirable to use prediction which requires no future signals. However, typically, interpolation provides better performance than prediction.

The communications channel introduces noise, namely, Y(n,k)=X(n,k)H(n,k)+w(n,k) where w(n,k) is the additive noise introduced by the channel. As a result, the accuracy of the computed H values at the pilots is affected by the noise. Some complicated approaches have been developed to minimize the noise effect on the estimation. One of such approaches is called “Wiener filter” or “Minimum Mean Square Error filter”. The channel transfer function correlation matrix is computed, the knowledge of the fast-varying channel characteristics including noise should be used (but not available), and the matrix inversion is involved in the computation. Its implementation is quite complicated.

Therefore, there is a need for techniques for computing optimal interpolation filter coefficients on-line effectively and efficiently. Additionally, it is desired that the interpolation filter be asymmetric using less taps (or no taps for prediction) in one side than the other side to reduce both the signal storage requirement for time-domain interpolation and the boundary effect for the frequency-domain interpolation. It is also desired that the interpolation filters have more flexibility to be optimized to various channel conditions.

### BRIEF SUMMARY OF THE INVENTION

A method for channel estimation in a wireless communication system includes the following steps. Channel transfer finction is computed at continual and scattered pilot cells using transmitted and received signals at the continual and scattered pilot cells. Time-domain adaptive interpolation is performed to obtain channel transfer function at non-pilot cells of the scattered pilot tones using the channel transfer function computed at continual and scattered pilot cells. Frequency-domain adaptive interpolation is performed to obtain channel transfer function at non-pilot cells of non-pilot tones using the channel transfer function computed at continual and scattered pilot cells.

The following detailed description and the accompanying drawings provide a better understanding of the nature and advantages of the present invention.

### BRIEF DESCRIPTION OF THE DRAWINGS

FIG. 1 is a block diagram of an OFDM-based wireless receiver;

FIG. 2 shows the pilot insertion pattern in DVB-T and DVB-H;

FIG. 3 shows a block diagram of the interpolator-based channel estimator;

FIG. 4 shows interpolation-by-three of two-sided signal;

FIG. 5 shows interpolation-by-three of one-sided signal;

FIG. 6 is a plot showing time-domain interpolator performance (50 Hz Doppler);

FIG. 7 is a plot showing time-domain interpolator performance (150 Hz Doppler);

FIG. 8 is a plot showing frequency-domain interpolator performance (small dispersion);

FIG. 9 is a plot showing frequency-domain interpolator performance (large dispersion);

FIG. 10 is a plot showing the FFT of the frequency-domain LMS adaptive interpolator coefficients and the input;

FIG. 11 is a plot showing the FFT of the time-domain LMS adaptive interpolator coefficients, the fixed interpolator coefficients and the filter input;

FIG. 12 is a plot showing asymmetric time-domain adaptive interpolator coefficients;

FIG. 13 is a plot showing FFT of the asymmetric time-domain adaptive interpolator coefficients and its input;

FIG. 14 is a plot showing asymmetric frequency-domain adaptive interpolator coefficients;

FIG. 15 is a plot showing FFT of the asymmetric frequency-domain adaptive interpolator coefficients and its input;

FIG. 16 is a plot showing asymmetric frequency-domain adaptive interpolator helps reduce boundary effect;

FIG. 17 is a plot showing convergence of the asymmetric frequency-domain interpolation; and

FIG. 18 is a block diagram of an OFDM-based wireless receiver in accordance with an embodiment of the invention.

### DETAILED DESCRIPTION OF THE INVENTION

In accordance with the present invention, the interpolation filter coefficients are adaptively adjusted on-line to optimize the estimation accuracy and minimize the mean square error. In one embodiment, the low-complexity least-mean-square (LMS) adaptation algorithm is used for the coefficient adaptation. Using the LMS algorithm, prior knowledge of the channel characteristics including noise is not needed. The interpolation filter automatically converges to the optimal setting to minimize the mean squared error. The computation in the LMS algorithm is simple and the complexity is low. As the channel conditions change, the filter coefficients will automatically re-converge to the new optimal setting. Therefore, the interpolation filter improves performance with possibly a fewer number of taps.

Complex coefficients are used for the interpolation filter to improve the performance, shorten the filter span, and allow asymmetric distribution of the filter taps. The asymmetry allows using less future signals in the time-domain interpolation (or no future signals in time-domain prediction) to help reduce the storage requirement, and greatly reduces the boundary effect for the frequency-domain interpolation.

I. Compute the Channel Transfer Functions at Pilot Tones

At the pilot tones, the transmitted signals X(n,k) are known by the receiver. The received signals Y(n,k) at those pilot tones are available at the receiver. The channel transfer functions H(n,k) are simply computed as H(n,k)=Y(n,k)/X(n,k).

II. Time Domain Interpolation

The interpolation is first performed in the time domain. The time-domain interpolation is needed because at some pilot tones (called scattered pilot tones in DVB-T/DVB-H for example), the pilot is transmitted only part of the time. In DVB-T/DVB-H, the scattered pilot cells are transmitted every four other symbols. Time-domain interpolation is performed to estimate the channel transfer functions at non-pilot cells of the scattered pilot tones.

A. Coefficient Update

The first step is the interpolation filter coefficients adaptation. In one embodiment, in cases such as DVB-T/DVB-H system, the adaptation is based on continual pilots. The adaptation takes the following three sub-steps.

Step (1): Use the current interpolation filters to perform interpolation at the continual pilot tones. Suppose there are P continual pilot tones at sub-carriers k₁, k₂, . . . k_{P}. At each continual pilot tone kᵢ (i=1,2, . . . P) (or a subset of the continual pilot tones), in every symbol (or a subset of symbols), the interpolation is performed using the current sets of interpolation filter coefficients. For DVB-T/DVB-H, there are three sets of time-domain interpolation filter coefficients. These three filters estimate H(4m+1,ki), H(4m+2,ki), H(4m+3,ki), respectively, using H(4(m−M1+1),ki), H(4(m−M1+2),ki), . . . H(4(m−1),ki), H(4m,ki), H(4(m+1),ki), . . . H(4(m+M2),ki), with M1 past and M2 future values of H. At the continual pilot tones, at symbol n, three interpolation filters are run to get three estimates of H(n,ki):
H1(n,ki)=ΣW1(n−1,m)H(n−1+4m,ki)(m=−M1+1,−M1+2, . . . −1,0,1, . . . M2)
H2(n,ki)=ΣW2(n−1,m)H(n−2+4m,ki)(m=−M1+1 −M1+2, . . . −1,0,1, . . . M2)
H3(n,ki)=ΣW3(n−1,m)H(n−3+4m,ki)(m=−M1+1,−M1+2, . . . −1,0,1, . . . M2)

Where WL(n−1,m) is the m-th coefficient ofthe L-th (L=1,2,3) interpolation filter updated in the previous symbol n−1. Each filter has M1+M2 coefficients. The number of coefficients may be the same or close for different filters, however, different number of coefficients is also possible. Furthermore, M2 can be zero (prediction instead of interpolation) for some or all filters.

Step (2): Compute the estimation errors. The channel transfer functions at the continual pilot tones H(n,ki) are computed in section I above. The estimation errors E1(n,ki), E2(n,ki), and E3(n,ki) are simply computed as the difference between H(n,ki) and the interpolation results H1(n,ki), H2(n,ki), and H3(n,ki), obtained in step (1) above:
E1(n,ki)=H(n,ki)−H1(n,ki),
E2(n,ki)=H(n,ki)−H2(n,ki),
E3(n,ki)=H(n,ki)−H3(n,ki),

Step (3): Update the interpolation filter coefficients. The interpolation filter coefficients are updated using the errors calculated in step (2) above. The three errors are used to update three interpolation filters, respectively:
W1(n,m)=W1(n−1,m)+μΣE1*(n,ki)H(N631 1+4m,ki) for summation over all or a subset of ki.
W2(n,m)=W2(n−1,m)+μΣE2*(n,ki)H(n−2+4m,ki) for m=−M1+1, −M1+2, . . . −1,0,1, . . . M2
W3(n,m)=W3(n−1,m)+μΣE3*(n,ki)H(n−3+4m,ki) for m=−M1+1, −M1+2, . . . −1,0,1, . . . M2

Note that * denotes complex conjugate, and μ is the update step size. The filter coefficient update can be performed at all or a subset of all continual pilots:
W1(n,m)=W1(n−1,m)+μΣE1*(n,ki)H(n−1+4m,ki) for summation over all or a subset of ki.
W2(n,m)=W2(n−1,m)+μΣE2*(n,ki)H(n−2+4m,ki) for summation over all or a subset of ki.
W3(n,m)=W3(n−1,m)+μΣE3*(n,ki)H(n−3+4m,ki) for summation over all or a subset of ki.

This method is called “block update”.

B. Interpolation at Scattered Pilot Tones

At the scattered pilot tone kj, if the pilot cell is not transmitted at symbol n, the nearest symbol before n which transmits pilot cell is symbol n−1 or n−2 or n−3. Accordingly, one of the interpolation filters (W1, W2 or W3) is used to calculate the estimate H(n,kj). If symbol n−1 transmits pilot at scattered pilot ki, then:
H(n,ki)=ΣW1(n,m)H(n−1+4m,ki) (summation over m=−M1+1, −M1+2, . . . −1,0,1, . . . M2)
If symbol n−2 transmits pilot at scattered pilot ki, then:
   H(n,ki)=ΣW2(n,m)H(n−2+4m,ki) (summation over m=−M1+1, −M1+2, . . . −1,0,1, . . . M2)
If symbol n−3 transmits pilot at scattered pilot ki, then:
   H(n,ki)=ΣW3(n,m)H(n−3+4m,ki) (summation over m=−M1+1, −M1+2, . . . −1,0,1, . . . M2)

The time-domain interpolation is performed at every scattered pilot tone to obtain transfer function estimation at the non-pilot cells of the scattered pilot tones.

C. Alternative Methods for Update

In one alternative embodiment, as we sweep across continual pilots, the updated coefficients can be used for the estimation. Suppose the continual pilot tones are at carriers k₁, k₂, . . . kₚ. First we take over the coefficients at the end of the previous symbol denoted as n−1:
W1(n,k₁,m)=W1(n−1,kₚ,m)
W2(n,k₁,m)=W2(n−1,kₚ,m)
W3(n,k₁,m)=W3(n−1,kₚ,m)

Starting from k₁=k₂, we run the following loop:

Compute the estimates
H1(n,kᵢ)=ΣW1(n,kᵢ₋₁,m)H(n−1+4m,ki)(m=−M1+1,−M1+2, . . . −1,0,1, . . . M2)
H2(n,kᵢ)=ΣW2(n,kᵢ₋₁,m)H(n−2+4m,ki)(m=−M1+1,−M1+2, . . . −1,01, . . . M2)
H3(n,kᵢ)=ΣW3(n,kᵢ₋₁,m)H(n−3+4m,ki)(m=−M1+1,−M1+2, . . . −1,0,1, . . . M2)
And the errors
E1(n,kᵢ)=H(n,kᵢ)−H1(n,kᵢ),
E2(n,kᵢ)=H(n,kᵢ)−H2(n,kᵢ),
E3(n,kᵢ)=H(n,kᵢ)−H3(n,kᵢ).
Then update the coefficients:
W1(n,kᵢ,j)=W1(n,kᵢ₋₁,j)+μE1*(n,kᵢ)H(n−1+4m,kᵢ) for m=−M1+1,−M1+2, . . . −1,0,1, . . . M2
W2(n,kᵢ,j)=W2(n,kᵢ₋₁,j)+μE2*(n,kᵢ)H(n−2+4m,kᵢ) for m=−M1+1,−M1+2, . . . −1,0,1, . . . M2
W3(n,kᵢ,j)=W3(n,kᵢ₋₁,j)+μE3*(n,kᵢ)H(n−3+4m,kᵢ) for m=−M1+1,−M1+2, . . . −1,0,1, . . . M2

Move kᵢ to kᵢ₊₁, repeat this loop until the last continual pilot tone kₚ.

In another alternative embodiment, the frequency of the LMS updates may be reduced. For example, in every symbol, only one of the filters may be updated and three filters are updated in turn. Of course, with reduced updates, the tracking performance is degraded.

In yet another alternative embodiment, the LMS update may be repeated for one or more times in the same symbol to speed up the convergence. Specifically, based on the continual pilot signals in one symbol, the LMS update is first performed as described above in section II-A or section II-C. After the update, a new set of coefficients is obtained. The LMS update is repeated starting from the new set of coefficients, leading to a newer set of coefficients. The same process may be repeated more times. This may be useful in reducing the acquisition time.

III. Frequency-domain Interpolation

After time-domain interpolation, we have estimate H(n,k) at all continual and scattered pilot tones. As a result, in every symbol, at every three other tones, H(n,k) is available. Without loss of generality, suppose the first such tone is a multiple of 3, we denote those values as H(n,3s) for s=S0, S0+1, . . . S0+S−1. In frequency-domain interpolation, we compute H(n,3s+1) and H(n,3s+2) for s=S0, S0+1, . . . S0+S−2. (Assuming the first and the last carrier are pilot tones.)

A. Update frequency-domain interpolation filters

1. With Pilot Symbols

If there are pilot symbols in which all the sub-carriers send pilots (i.e., there are continual pilot symbols), the interpolation filters update can be easily performed in those pilot symbols. If symbol n is a continual pilot symbol, at carrier k, we estimate the channel transfer function H(n,k) twice as:
H1(n,k)=ΣV1(n−1,j)H(n,k−1+3j)(j=−J1+1. −J1+2, . . . −1,0,1, . . . J2)
H2(n,k)=ΣV2(n−1,j)H(n,k−2+3j)(j=−J1+1, −J1+2, . . . −1,0,1, . . . J2)

Estimation errors are then computed:
E1(n,k)=H(n,k)−H1(n,k),
E2(n,k)=H(n,k)−H2(n,k).

The errors are used to update interpolation filter coefficients:
V1(n,j)=V1(n−1,j)+μE1*(n,k)H(n,k−1+3j) for j=−J1+1, −J1+2, . . . −1,0,1, . . . J2
V2(n,j)=V2(n−1,j)+μE2*(n,k)H(n,k−2+3j) for j=‘J11+1, −J1+2, . . . −1,0,1, . . . J2

The update can be performed at all or a subset of all the carriers (block update):
V1(n,j)=V1(n−1,j)+μΣE1*(n,k)H(n,k−1+3j) (summation over all or a subset of k)
V2(n,j)=V2(n−1,j)+μΣE2*(n,k)H(n,k−2+3j) (summation over all or a subset of k)

As an alternative, as we sweep across carriers, we can use updated coefficients for the estimation. First we take over the coefficients at the end of the previous pilot symbol update denoted as n−N:
V1(n,kmin,j)=V1(n−N,kmax,j)
V2(n,kmin,j)=V2(n−N,kmax,j)

Starting from k=kmin+1, we run the following loop:

Compute the estimates:
H1(n,k)=ΣVl(n,k−1 ,j)H(n,k−1+3j)(j=−J1+1, −J1+2,. . . −1,0,1, . . . J2)
H2(n,k)=ρV2(n,k−1 ,j)H(n,k−2+3j)(j=−J1+1, −J1+2, . . . −1,0,1, . . . J2)

And the errors:
E1(n,k)=H(n,k)−H1(n,k),
E2(n,k)=H(n,k)−H2(n,k).

And update the coefficients:
V1(n,k,j)=V1(n,k−l,j)+μE1*(n,k)H(n,k−1+3j) for j=−J1+1, −J1+2, . . . −1,0,1, . . . J2
V2(n,k,j)=V2(n,k−1,j)+μE2*(n,k)H(n,k−2+3j) for j=−J1+1, −J1+2, . . . −1,0,1, . . . J2

Increase k by 1 (or some integer), repeat this loop until the last k kmax.

2. Without pilot symbols

If there is no pilot symbol in which all the sub-carriers send pilot (i.e., there are no continual pilot symbols), H(n,k) used in the error calculation is not available. This is the case for DVB-T/DVB-H. In that case, we can perform the frequency-domain interpolation for all the non-pilot carriers based on the filter coefficients updated in the previous symbol first, followed by the filter coefficients update. In one embodiment, the filter coefficients update can be decision-based. The error signals for the coefficient update are calculated based on decisions:
If k=3K+1, (K is an integer) we use filter 1 to compute the channel transfer function estimate
   H(n,k) as H(n,k)=ΣV1(n−1,j)H(n,k−1+3j) (sum over j=−J1+1, −J1+2, . . . −1,0,1, . . . J2).
If k=3K+2, we use filter 2 to compute the channel transfer function estimate H(n,k) as
   H(n,k)=ΣV2(n−1,j)H(n,k−2+3j)(j=−J1+1, −J 1+2, . . . −1,0,1, . . . J2).

After we calculate H(n,k), we compute the estimate of X(n,k) by computing X(n,k)=Y(n,k)/H(n,k). From X(n,k), the estimate of the transmitted signal X(n,k) is X(n,k) which is obtained through decisions. The error is calculated as:
E(n,k)=H(n,k)−H(n,k)

Where H(n,k)=Y(n,k)/X(n,k). E(n,k) is used to update one of the 2 sets of filter coefficients (V1 or V2):
If k=3K+1, V1 is updated:
   V1(n,j)=V1(n−l,j)+μE*(n,k)H(n,k−1+3j) for j=−J1+1, −J1+2, . . . −1,0,1, . . . J2
If k=3K+2, V2 is updated:
   V2(n,j)=V2(n−1,j)+μE*(n,k)H(n,k−1+3j) for j=−J1+1, −J1+2, . . . −1,0,1, . . . J2

We can use all possible carriers to update VI and V2:
If k=3K+1, V1 is block-updated:
   V1(n,j)=V1(n−1,j)+μΣE*(n,k)H(n,k−1+3j) (sum over all or a subset of k)
If k=3K+2, V2 is block-updated:
   V2(n,j)=V2(n−1,j)+μΣE*(n,k)H(n,k−2+3j) (sum over all or a subset of k)

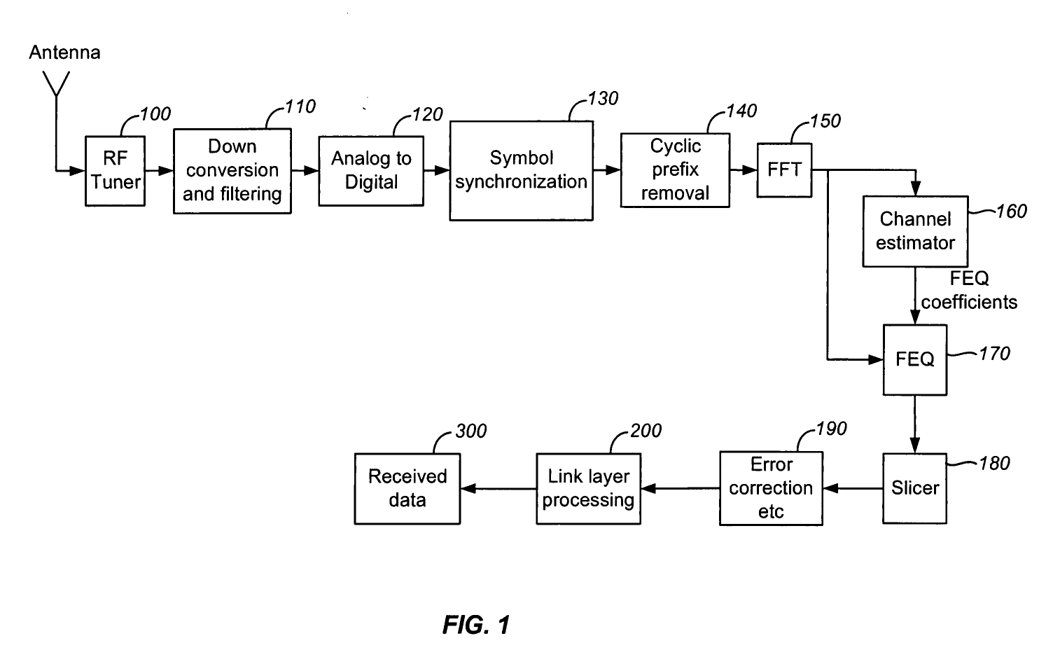

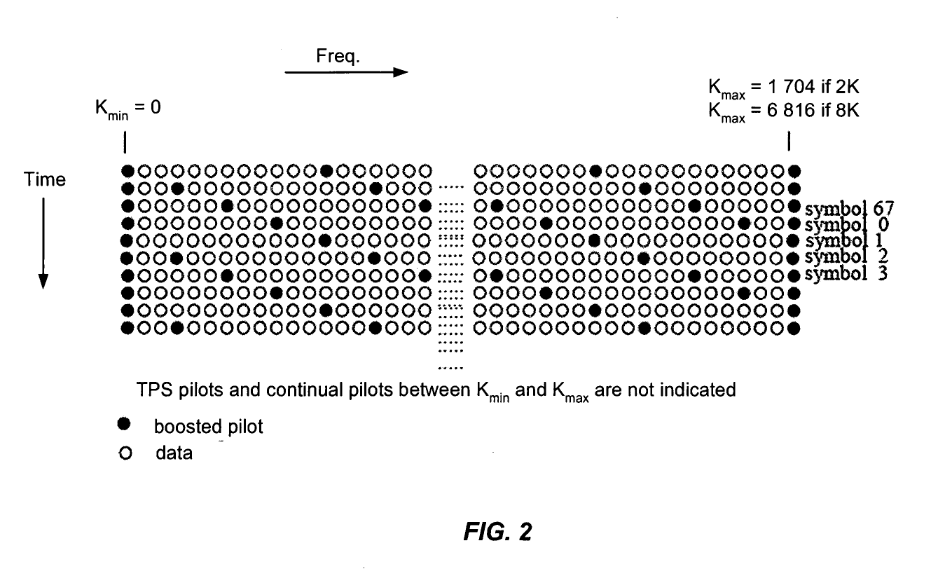

Decision errors may affect the filter coefficient update and may even cause filter to diverge. The block diagram in FIG. 19 will be used to describe an embodiment in which this potential problem is addressed. FIG. 19 is a block diagram of an OFDM-based wireless receiver which is similar to that in FIG. 1 except that subtract block 610, compare block 620, and select block 630 have been added. In FIG. 19, the error E(n,k) is computed by subtract block 610 and then compared to a pre-set threshold via compare block 620. For example, the absolute values of the real and imaginary part (or the magnitude) of E(n,k) are computed and compared with a pre-set threshold to decide if this E(n,k) will be used for the update. If the computed error is larger than the threshold, compare block 620 selects 0 (zero) via select block 630, thus skipping the update for this carrier. If the computed error is smaller than the threshold, compare block 620 selects the computed error E(n,k) via select block 630 for updating this carrier. In another embodiment, the interpolation is performed based on the recently updated coefficients:
If k=3K+1, (K is an integer) we use filter 1 to compute the channel transfer function estimate
   H(n,k) as H(n,k)=ΣV1(n,K−1,j)H(n,k−1+3j) (sum over j=−J1+1, −J1+2, . . . −1,0,1, . . . J2).
If k=3K+2, we use filter 2 to compute the channel transfer function estimate H(n,k) as
   H(n,k)=ΣV2(n,K−3 1,j)H(n,k−1+3j)(j=−J1+1, −J1+2, . . . −1,0,1, . . . J2).

We then use newly calculated estimates H(n,k) to compute X(n,k)=Y(n,k)/H(n,k), then X(n,k) from X(n,k) through decision, then H(n,k)=Y(n,k)/X(n,k). The error E(n,k)=H(n,k)−H(n,k) is used to update V1 or V2:
If k=3K+1, V1 is updated:
   V1(n,K,j)=V1(n,K−1,j)+μE*(n,k)H(n,k−1+3j) for j=−J1+1, −J1+2, . . . −1,0,1, . . . J2
If k=3K+2, V2 is updated:
   V2(n,Kj)=V2(n,K−1,j)+μE*(n,k)H(n,k−1+j) for j=J11,−J1+2, . . . −1,0,1, . . . J2

At the first carrier, the coefficient values are taken from the end of the previous symbol. Similar to the alternative time-domain interpolation update methods discussed in section II-C, the LMS update for the frequency-domain interpolator update may be performed on a subset of carriers to reduce the complexity, or repeatedly to speed up the convergence.

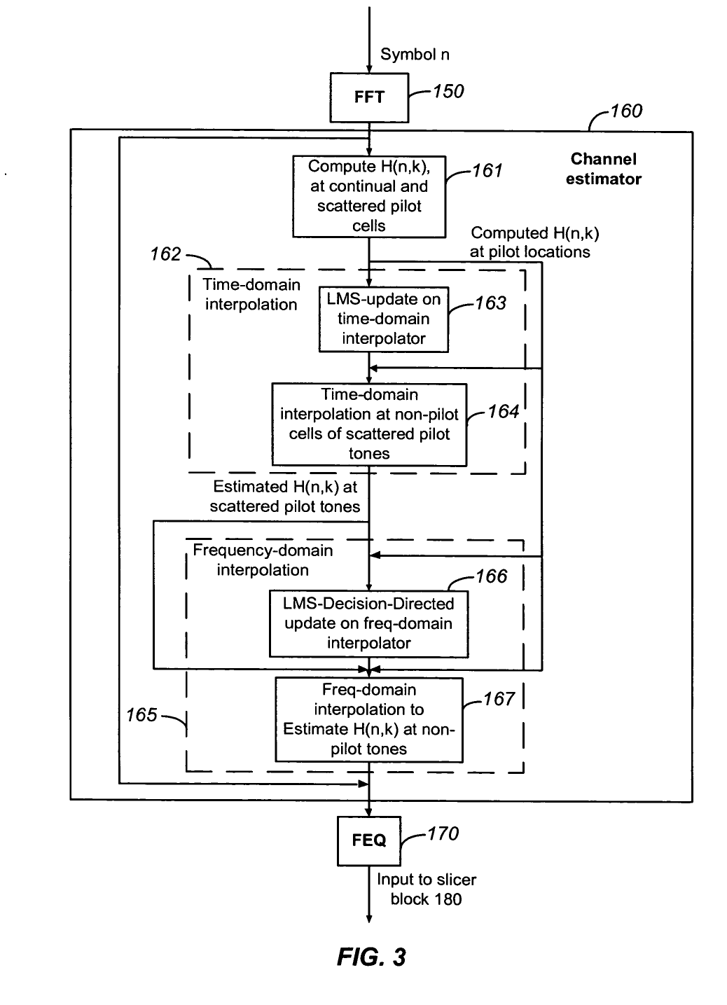

FIG. 3 shows the flow chart of the interpolation process in accordance with an embodiment of the invention, including time-domain and frequency-domain interpolation. The channel estimator 160 includes blocks 161, 162 and 165. Block 161 computes the channel transfer functions at the pilot cells, including the continual pilot cells and scattered pilot cells. The time-domain interpolator 162 includes blocks 163 and 164. Block 163 computes the time-domain interpolator coefficient updates based on the LMS algorithm. In block 164, the channel transfer functions are calculated using time-domain interpolation at the non-pilots cells of all the scattered pilot tones. After time-domain interpolation, the estimates through time-domain interpolation or computed values of the channel transfer functions at all the scattered pilot tones are available.

The frequency-domain interpolator 165 computes the channel transfer function estimates at all non-pilot tones. Block 165 includes blocks 166 and 167. Block 166 computes the frequency-domain interpolator coefficient updates based on the LMS algorithm. In block 167, the channel transfer functions are calculated using frequency-domain interpolation at all the non-pilot tones. After frequency-domain interpolation, the estimates of all the transfer functions at all the data carriers are available either through frequency-domain interpolation for all the non-pilot tones or the time-domain interpolator for the non-pilot cells of all the scattered pilot tones. The results are sent to FEQ 170 to set up the FEQ coefficients.

IV. Interpolation Filter Structure:

Typically, the interpolation filters are designed as low-pass digital filters. The bandwidth of the passband depends on the interpolation ratio. For example, for the time-domain interpolation in DVB-T/DVB-H systems, the interpolation ratio is 4, then the passband of the lowpass filter is ¼ of the Nyquest frequency. For frequency-domain interpolation in DVB-T/DVB-H systems, the interpolation ratio is 3, then the passband of the lowpass filter is ⅓ of the Nyquest frequency. The lowpass filters are typically implemented with real coefficients symmetrical around the center tap. Therefore, for the time-domain interpolation filter described in section II, M1=M2, and for the frequency-domain interpolation filter in section III, J1=J2.

However, in time-domain interpolation, we have the filter operation (take the first filter as example) as (see section II):
H(n,ki)=ΣW1(n,m)H(n−1+4m,ki) (summation over m=−M1+1,−M1+2, . . . −1,0,1, . . .M2)

For 0<m≦M2, n−1+4m>n. Therefore, we need “future” channel transfer function H(n−1+4m,ki) to compute H(n,ki). This requires storing all H values at the continual and scattered pilot tones for 4(M1+M2) symbols, and all the received signals Y(n,k) for 4M2 symbols for all the data carriers. Since the number of carriers is quite big (up to 8k in DVB-T), this requires a considerably large memory space. To reduce the memory requirement, it is desirable to reduce M2.

In one embodiment, complex asymmetric interpolation filter with M2<M1 is used. Complex filter, although doubles the computations per tap, helps improve the performance and reduce the number of taps, especially helps reduce M2. To further reduce the memory requirement, M2 can be even zero for some of the filters. For example, if M2 is zero for the first filter but M2=1 for the other 2 filters, we need to store only 3 symbols for all the data carriers.

In frequency-domain interpolation, all the inputs to the interpolation filter are within the same symbol. There is no “storage of future” issue. The main issue is at the boundary. If J1=J2, we need 3J1 and 3J2 carriers on each side of the carrier computed. This is not a problem except at the boundaries where not enough carriers are available to the interpolation filter. As a result, the estimation of H is degraded at both ends. To resolve this issue, it is desirable to use asymmetric filter with small J1 or small J2 (as small as 1). This is made possible by using complex filters.

interpolation filter can be pre-designed offline based on the worst-case conditions. For example, for the time-domain interpolation, the filter should cover the highest Doppler frequency and for the frequency-domain interpolation, the filter should cover the longest delay dispersion. The stopband of the interpolation filters should have enough attenuation to ensure good interpolation accuracy and noise rejection. Note that the noise is typically white, covering all the frequencies. If the passband of the filter is ⅓ of the entire bandwidth, ⅔ of the noise is in the stopband and thus can be rejected. Hence, to reject noise, the interpolation filter passband should be as narrow as possible, as long as the Doppler frequency or the delay dispersion can be covered. On the other hand, deep stopband attenuation puts heavy burden to the interpolation filter resources. Hence, the stopband rejection should not be too deep, but just deep enough to ensure the performance degradation is negligible.

For mobile environment, the Doppler frequency, the delay dispersion and the channel noise conditions change frequently. The pre-designed interpolation filters are never optimized to the fast-varying environment. The adaptive interpolation filter, in accordance with the invention, provides the ideal solution to the optimum filter setting for the optimum performance under any channel conditions.

In the real wireless communications environment, the Doppler frequency, delay dispersion and channel noise conditions are not necessarily all at their worst conditions. The interpolation filters have limited resources due to mainly the filter length (complexity) constrain. Adaptive interpolation, in accordance with the invention, allows the interpolation filters to optimize their setting to optimize the system performance under any particular fast varying channel conditions.

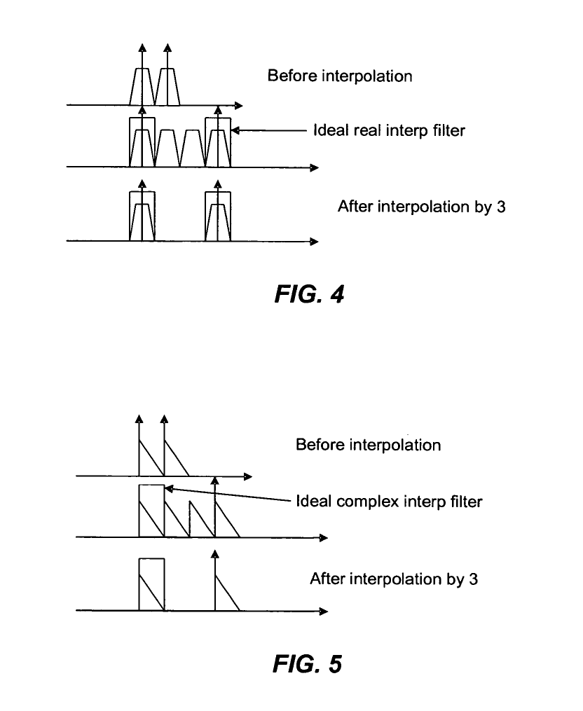

The use of complex filter coefficients allows asymmetric filter responses which may be optimal for some channel conditions. For example, for the multi-path delay dispersion, we should pick the first path as the beginning so that the signals from other paths may be covered by the cyclic prefix. That means that all the other paths have longer delay, thus the delay dispersion is one-sided. In that case, the optimal interpolation filter response should be one-sided. This is made possible by using complex coefficients and adjusting the coefficients on-line. The one-sided response helps reducing the noise effect and enabling the compensation of twice as large delay dispersion as the maximum delay dispersion the interpolation filter with two-sided response can cover (see FIGS. 4 and 5).

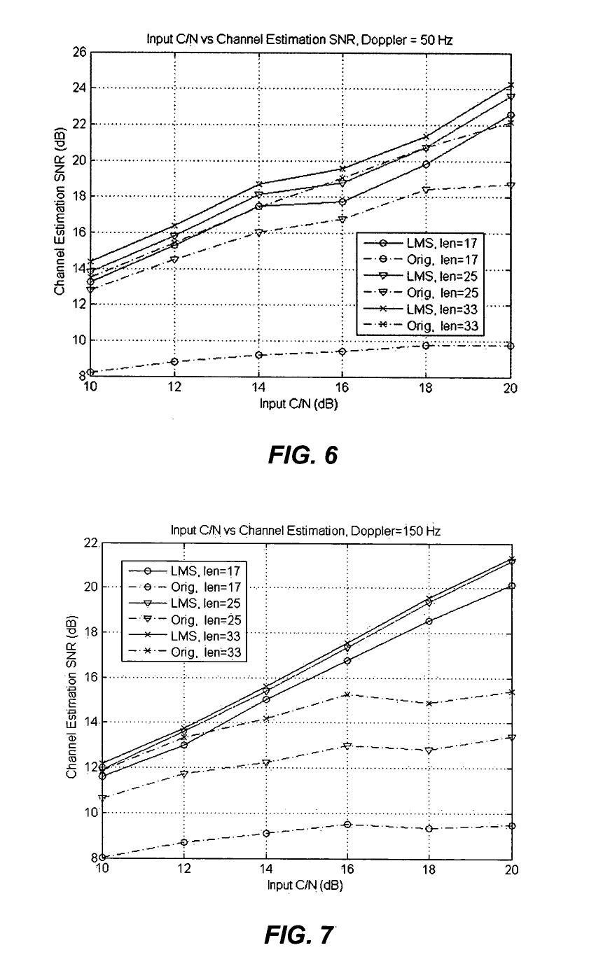

FIGS. 6 and 7 compare the performance of the time-domain interpolators using LMS adaptation algorithm and the fixed-coefficients designed for the worst-case Doppler frequency. In FIG. 6, a relatively low Doppler frequency of 50 Hz is used, and in FIG. 7, a high Doppler frequency of 150 Hz is used. The length of the interpolator is 17, 25 or 33.

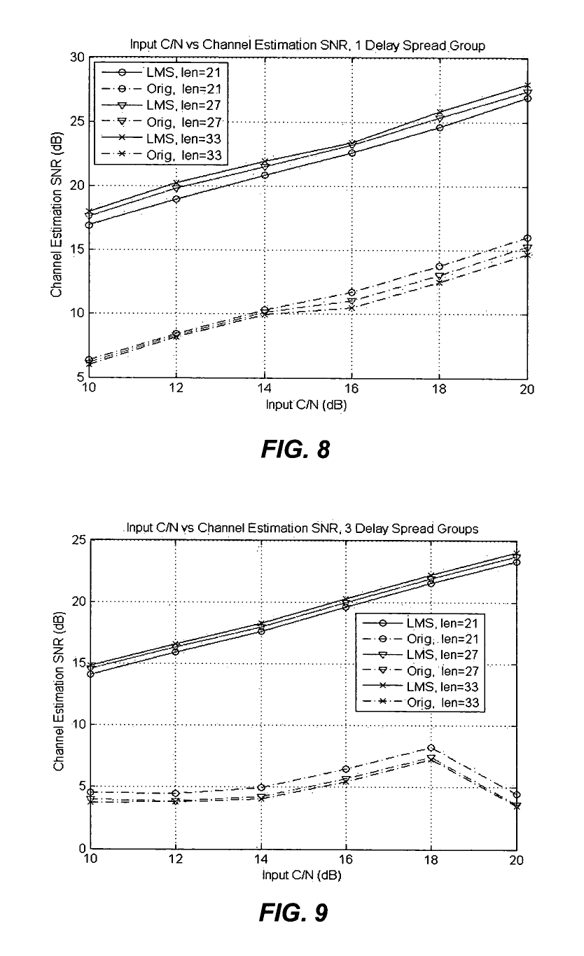

FIGS. 8 and 9 compare the performance of the frequency-domain interpolators using LMS adaptation algorithm and the fixed-coefficients designed for the worst-case delay dispersion. In FIG. 8, a relatively small delay dispersion of [0 0.2 0.5 1.6 2.3 5.0] μS is used, and in FIG. 9, a large delay dispersion of {[0 0.2 0.5 1.6 2.3 5.0] μS, [0 0.2 0.5 1.6 2.3 5.0]+50 μS, [0 0.2 0.5 1.6 2.3 5.0]+100 μA} is used. The length of the interpolator is 21, 27 or 33.

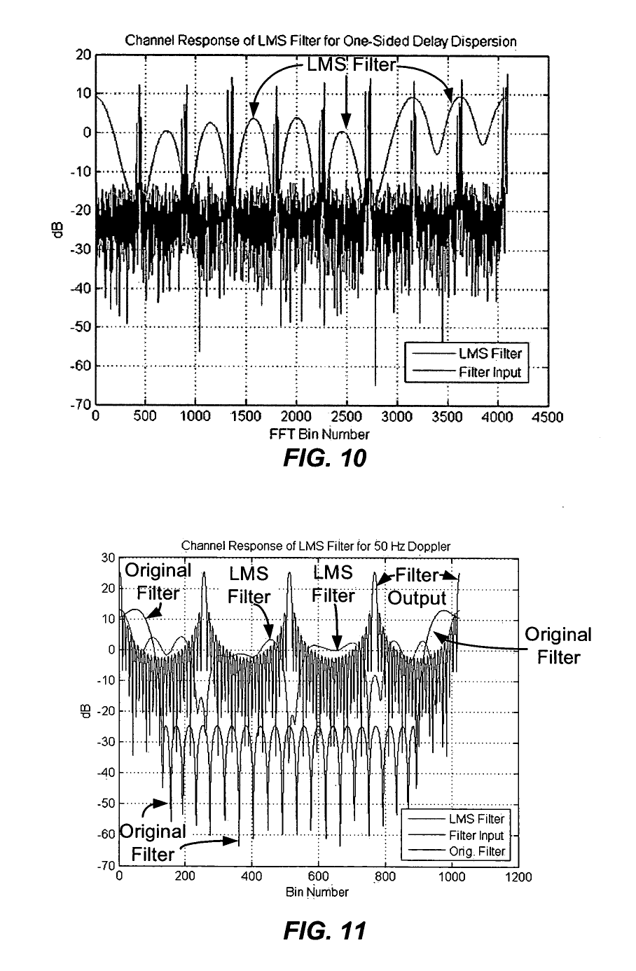

FIG. 10 shows the response of the frequency-domain LMS adaptive interpolator with the one-sided delay dispersion {[0 0.2 0.5 1.6 2.3 5.0] μS, [0 0.2 0.5 1.6 2.3 5.0]+50 μS, [0 0.2 0.5 1.6 2.3 5.0]+100 μS} at 12 dB input SNR and 21 taps. The FFT of the input to the interpolator is also shown in blue. The first three peaks from the right represent the three delay groups. The LMS interpolator allows these three peaks to pass. All the other peaks are in the nulls of the LMS adaptive interpolator, and thus removed.

FIG. 11 shows the FFT of the time-domain LMS adaptive interpolator, the fixed interpolator and the filter input. A moderate Doppler frequency of 50 Hz is used, with 12 dB input signal SNR. Twenty-five filter taps are used. Note that the passband is narrower in the adaptive interpolator than the fixed original filter since the Doppler is lower. The narrower passband allows less noise to pass thus improving performance. The stopband attenuation in the adaptive interpolator is relaxed to obtain just enough attenuation for this case. Deeper attenuation in the original interpolator is not necessary and sharp filters often create other problems and degrade performance. Obviously, the adaptive filter optimally uses the available filter resources to minimize the output mean squared error.

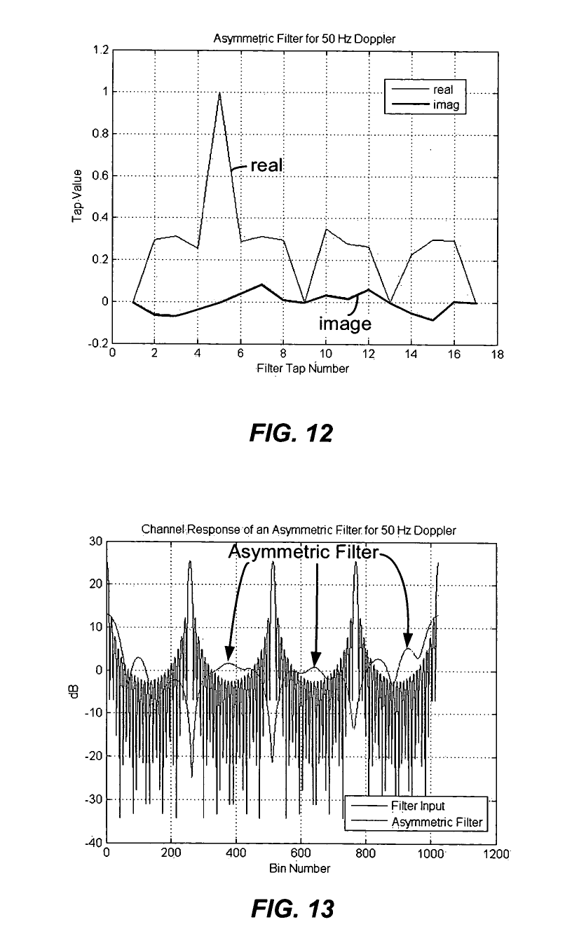

FIG. 12 shows asymmetric time-domain complex filter under 50 Hz Doppler frequency. With this asymmetric filter, only one “future” H value is needed thus the storage for the “future” symbols is much reduced. FIG. 11 shows the FFT of such a filter and its input.

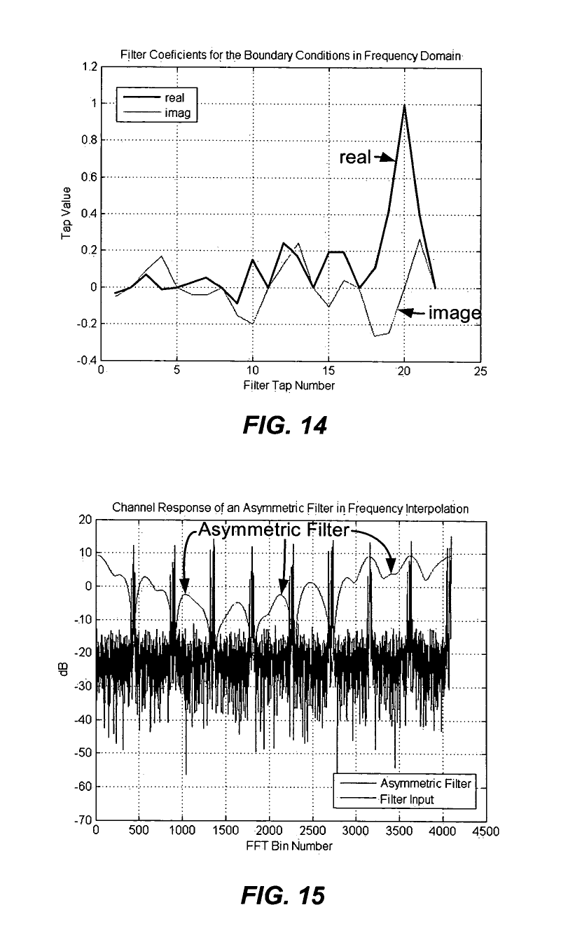

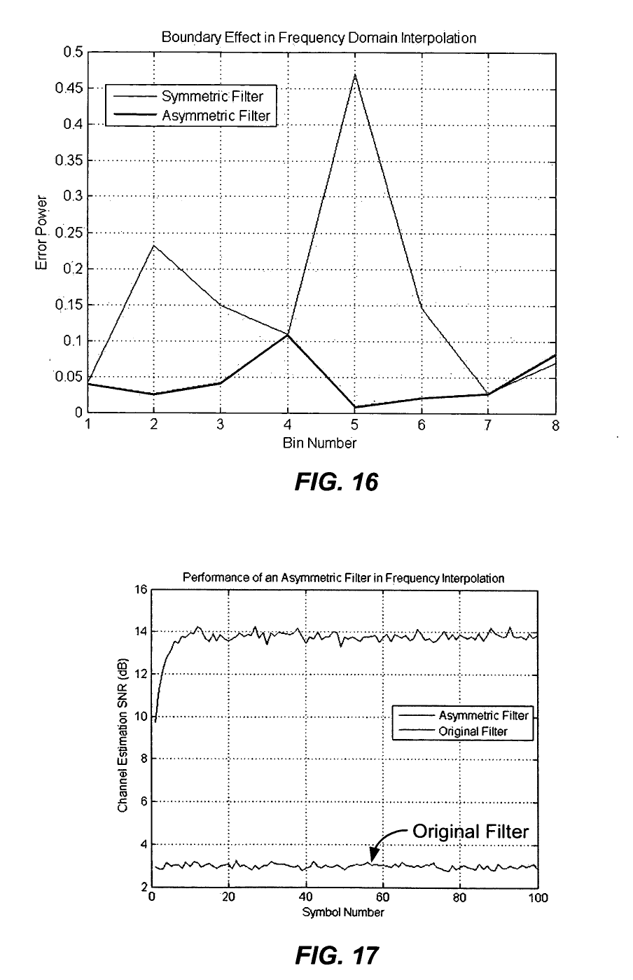

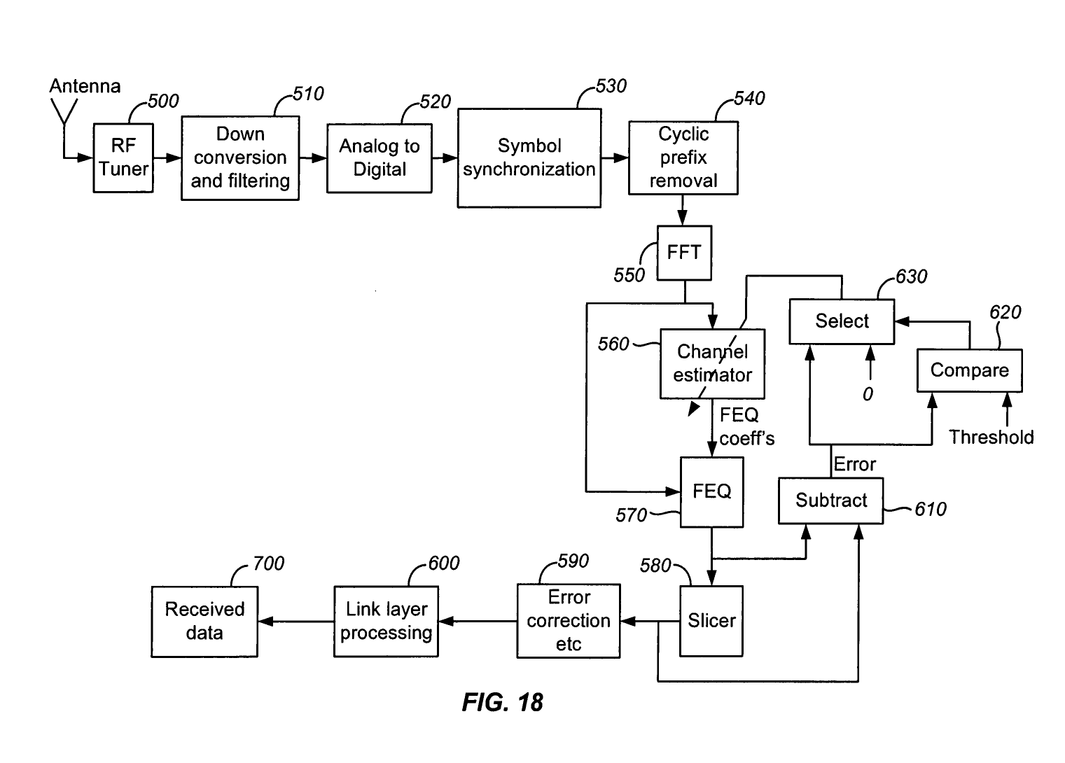

FIGS. 14 and 15 show the asymmetric frequency domain interpolator. The delay dispersion {[0 0.2 0.5 1.6 2.3 5.0] μS, [0 0.2 0.5 1.6 2.3 5.0]+50 μS, [0 0.2 0.5 1.6 2.3 5.0]+100 μs} is used at 12 dB input SNR and 21 taps. Asymmetric frequency-domain interpolator helps reducing the boundary effect, which is shown in FIG. 16. The convergence of this adaptive interpolation is shown in FIG. 17.

While the above provides a detailed description of various embodiments of the invention, many alternatives, modifications, and equivalents are possible. For example, while some embodiments of the adaptive channel estimation are describe in the context of DVB-T and DVB-H, the adaptive channel estimation in accordance with the invention can also be used in implementations of other wireless standards. Hence, the scope of this invention should not be limited to the embodiments described, but is instead defined by the following claims.

What is claimed is:

1. A method for channel estimation in a wireless communication system, comprising:
(I) computing channel transfer function at continual and scattered pilot cells using transmitted and received signals at the continual and scattered pilot cells;
(II) performing time-domain adaptive interpolation to obtain channel transfer function at non-pilot cells of scattered pilot tones using the computed channel transfer function from step (I); and
(III) performing frequency-domain adaptive interpolation to obtain channel transfer function at non-pilot cells of non-pilot tones using the computed channel transfer function from step (I).

2. The method of claim 1 wherein step (II) further comprises:
(A) updating interpolation filter coefficients, comprising the steps of:
(1) using current interpolation filter coefficients, performing interpolation at continual pilot tones;
(2) computing estimation errors by comparing the computed channel transfer function from step (I) in claim 1 with interpolation results from step (1);
(3) using the computed estimation errors, updating interpolation filter coefficients at at least a subset of continual pilot tones; and
(B) using the updated interpolation filter coefficients, performing interpolation at scattered pilot tones to obtain transfer function estimation at the non-pilot cells of the scattered pilot tones.

3. The method of claim 1 wherein step (III) further comprises:
(A) updating interpolation filter coefficients, comprising the steps of:
(1) using current interpolation filter coefficients, performing interpolation at non-pilot cells of non-pilot tones;
(2) using the interpolation results from step (1), compensating channel distortion to transmitted signal;
(3) estimating the transmitted signal through decision based on the compensated received signal from step (2);
(4) computing the difference before and after the decision, and skipping steps (5)-(7) if the magnitude of the difference is larger than a pre-set threshold;
(5) computing channel transfer function at non-pilot tones based on received signal and the decision of the transmitted signal;
(6) computing estimation errors by comparing the computed channel transfer function from step (5) with the interpolation results from step (1); and
(7) using the computed estimation errors from step (6), updating interpolation filter coefficients at at least a subset of non-pilot tones.

4. The method of claim 2 wherein step (A) is carried out based on the LMS algorithm.

5. The method of claim 3 wherein steps (5)-(7) are carried out based on the LMS algorithm.

6. The method of claim 2 wherein the interpolation filter coefficients are complex asymmetrical coefficients.

7. The method of claim 3 wherein the interpolation filter coefficients are complex asymmetrical coefficients.

8. The method of claim 1 wherein step (III) further comprises:
(A) updating interpolation filter coefficients, comprising the steps of:
(1) using current interpolation filter coefficients, performing interpolation at non-pilot tones;
(2) using the interpolation results from step (1), compensating channel distortion to transmitted signal;
(3) estimating the transmitted signal through decision based on the compensated received signal from step (2);
(4) computing a decision error;
(5) if the magnitude of the decision error is smaller than a pre-set threshold, updating the interpolation filter coefficients, comprising the steps of:
(a) computing channel transfer function at non-pilot tones based on received signal and the decision of the transmitted signal;
(b) computing estimation errors by comparing the computed channel transfer function from step (a) with the interpolation results from step (1); and
(c) using the computed estimation errors from step (b), updating interpolation filter coefficients at at least a subset of non-pilot tones.

9. The method of claim 1 wherein step (II) further comprises:
(A) updating interpolation filter coefficients at a predetermined number of continual pilot tones, comprising the steps of:
(1) using interpolation filter coefficients from a preceding symbol, performing interpolation at a first one of the predetermined number of continual pilot tones;
(2) computing estimation errors by comparing the computed channel transfer function from step (I) in claim 1 with interpolation results from step (1);
(3) using the computed estimation errors, updating interpolation filter coefficients at the first one of the predetermined number of continual pilot tones;
(4) repeating steps (1)-(3) for each of the remaining continual pilot tones of the predetermined number of continual pilot tones; and
(B) using the updated interpolation filter coefficients, performing interpolation at scattered pilot tones to obtain transfer function estimation at the non-pilot cells of the scattered pilot tones.

10. The method of claim 1 wherein step (II) further comprises:
(A) updating interpolation filter coefficients based on the LMS algorithm; and
(B) using the updated interpolation filter coefficients, performing interpolation at scattered pilot tones to obtain transfer function estimation at the non-pilot cells of the scattered pilot tones.

11. The method of claim 10 wherein step (A) further comprises:
(1) using current interpolation filter coefficients, performing interpolation at continual pilot tones;
(2) computing estimation errors by comparing the computed channel transfer function from step (I) in claim 1 with interpolation results from step (1); and
(3) using the computed estimation errors, updating interpolation filter coefficients at at least a subset of continual pilot tones.

12. The method of claim 10 wherein step (A) further comprises:
(1) using updated interpolation filter coefficients from a preceding symbol, performing interpolation at a first one of a predetermined number of continual pilot tones;
(2) computing estimation errors by comparing the computed channel transfer function from step (I) in claim 1 with interpolation results from step (1);
(3) using the computed estimation errors, updating interpolation filter coefficients at the first one of the predetermined number of continual pilot tones; and
(4) repeating steps (1)-(3) for each of the remaining continual pilot tones of the predetermined number of continual pilot tones.

13. The method of claim 1 wherein step (III) further comprises:
(A) updating interpolation filter coefficients based on the LMS algorithm; and
(B) using the updated interpolation filter coefficients, performing interpolation at non-pilot tones.

14. The method of claim 13 wherein step (A) further comprises:
(1) using current interpolation filter coefficients, performing interpolation at continual pilot symbols;
(2) computing estimation errors by comparing the computed channel transfer function from step (I) in claim 1 with interpolation results from step (1); and
(3) using the computed estimation errors, updating interpolation filter coefficients at at least a subset of continual pilot symbols.

15. The method of claim 13 wherein step (A) further comprises:
(1) using updated interpolation filter coefficients from a preceding symbol, performing interpolation at a first one of a predetermined number of continual pilot symbols;
(2) computing estimation errors by comparing the computed channel transfer function from step (I) in claim 1 with interpolation results from step (1);
(3) using the computed estimation errors, updating interpolation filter coefficients at the first one of the predetermined number of continual pilot symbols; and
(4) repeating steps (1)-(3) for each of the remaining continual pilot symbols of the predetermined number of continual pilot symbols.

16. A method for channel estimation in a wireless communication system, comprising:
(I) computing channel transfer functions at continual and scattered pilot cells using transmitted and received signals at the continual and scattered pilot cells;
(II) using time-domain adaptive interpolation, computing channel transfer function at non-pilot cells of scattered pilot tones, comprising the steps of:
(A) updating interpolation filter coefficients, comprising the steps of:
(1) using current interpolation filter coefficients, performing interpolation at continual pilot tones;
(2) computing estimation errors by comparing the computed channel transfer function from step (I) with interpolation results from step (1);
(3) using the computed estimation errors, updating interpolation filter coefficients at at least a subset of continual pilot tones;
(B) using the updated interpolation filter coefficients, performing interpolation at scattered pilot tones to obtain transfer function estimation at the non-pilot cells of the scattered pilot tones;
(III) using frequency-domain adaptive interpolation, computing channel transfer function at non-pilot cells of non-pilot tones, comprising the steps of:
(A) updating interpolation filter coefficients, comprising the steps of:
(1) using current interpolation filter coefficients, performing interpolation at non-pilot tones;
(2) using the interpolation results from step (III)-(A)-(1), compensating channel distortion to transmitted signal;
(3) estimating the transmitted signal through decision based on the compensated received signal from step (III)-(A)-(2);
(4) computing a decision error;
(5) if the magnitude of the decision error is smaller than a pre-set threshold, updating the interpolation filter coefficients, comprising the steps of:
(a) computing channel transfer function at non-pilot tones based on received signal and the decision of the transmitted signal;
(b) computing estimation errors by comparing the computed channel transfer function from step (a) with the interpolation results from step (III)-(A)-(1); and
(c) using the computed estimation errors from step (b), updating interpolation filter coefficients at at least a subset of non-pilot tones.

17. A method for channel estimation in a wireless communication system, comprising:
(I) computing channel transfer functions at continual and scattered pilot cells using transmitted and received signals at the continual and scattered pilot cells;
(II) using frequency-domain adaptive interpolation, computing channel transfer function at non-pilot cells; and
(III) using time-domain adaptive interpolation, computing channel transfer function at non-pilot cells of non-pilot symbols.

18. The method of claim 17 wherein step (II) further comprises:
(A) updating interpolation filter coefficients based on the LMS algorithm; and
(B) using the updated interpolation filter coefficients, performing interpolation at non-pilot tones.

19. The method of claim 18 wherein step (A) further comprises:
(1) using current interpolation filter coefficients, performing interpolation at continual pilot symbols;
(2) computing estimation errors by comparing the computed channel transfer function from step (I) in claim 13 with interpolation results from step (1); and
(3) using the computed estimation errors, updating interpolation filter coefficients at at least a subset of continual pilot symbols.

20. The method of claim 18 wherein step (A) further comprises:
(1) using updated interpolation filter coefficients from a preceding symbol, performing interpolation at a first one of a predetermined number of continual pilot symbols;
(2) computing estimation errors by comparing the computed channel transfer function from step (I) in claim 1 with interpolation results from step (1);
(3) using the computed estimation errors, updating interpolation filter coefficients at the first one of the predetermined number of continual pilot symbols; and
(4) repeating steps (1)-(3) for each of the remaining continual pilot symbols of the predetermined number of continual pilot symbols.
